(19) United States
(12) Patent Application Publication
(10) Pub. No.: US 2008/0138983 A1
(43) Pub. Date: Jun. 12, 2008

(54) Method of forming tensile stress films for NFET performance enhancement

(75) Inventors: Hao-Ming Lien, Hsinchu (TW); Jim Cy Huang, Hsinchu (TW); Donald Y. Chao, Hsinchu (TW); Ling-Yen Yeh, Hsinchu (TW); Hun-Jan Tao, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/634,303

(22) Filed: Dec. 6, 2006

(51) Int. Cl. H01L 21/44

(52) U.S. Cl. 438/680; 257/E21.24

(57) ABSTRACT

A method of forming tensile stress films for NFET Performance enhancement, comprising the steps of: (a) providing a semiconductor substrate having a gate structure patterned thereon; (b) performing a deposition process to form a first dielectric film overlying the semiconductor substrate and covering the gate structure; (c) performing a curing process on the first dielectric film; (d) successively repeating the step (b) of deposition process and the step (c) of curing process at least once to form at least one second dielectric film on the first dielectric film until the total thickness of the first dielectric film and the at least one second dielectric film reaches a target thickness.

### TECHNICAL FIELD

The present invention relates to a method of forming a semiconductor device, and particularly to a method of forming tensile stress films for NFET performance enhancement.

### BACKGROUND

A principal factor in maintaining adequate performance in field effect transistors (FETs) is carrier mobility that affects the amount of current or charge in a doped semiconductor channel under control of a voltage placed on a gate electrode insulated from the channel by a very thin dielectric. A tensile SiN capping layer with uniaxial tensile strain has been strongly desired to enhance NMOS drive current. In detailed, after silicidation process, a tensile SiN film is provided on the NMOS device region, and the tensile SiN film also acts a contact etch stop layer (CESL). In order to avoid current leakage issues, a high tensile stress plasma-enhanced chemical vapor deposition (PECVD) SiN film with less than 450° C. process temperature has been introduced to be a capping layer for strained silicon application. Also, a SiN capping layer with post UV curing treatment is developed to reach more than 1.9 GPa tensile stress with low process temperature. However, the conventional method using the UV light irradiating a single SiN film of 600 Angstrom thickness for a period time makes the SiN film shrink and become a higher tensile SiN film that boots the silicon channel with higher drive-current gain for an NMOS device. What is needed in the art, therefore, is a novel method of forming tensile stress films for NFET performance enhancement.

### SUMMARY OF THE INVENTION

The present invention includes a method of forming tensile stress films for NFET performance enhancement. In one aspect, the present invention provides a method of forming tensile stress films, comprising the steps of: (a) providing a semiconductor substrate having a gate structure patterned thereon; (b) performing a deposition process to form a first dielectric film overlying the semiconductor substrate and covering the gate structure; (c) performing a curing process on the first dielectric film; (d) successively repeating the step (b) of deposition process and the step (c) of curing process at least once to form at least one second dielectric film on the first dielectric film until the total thickness of the first dielectric film and the at least one second dielectric film reaches a target thickness. In another aspect, the present invention provides a method of forming a tensile stress film having a target thickness, comprising the steps of: (a) providing a semiconductor substrate having a gate structure patterned thereon; (b) performing a deposition process to form a first SiN film overlying the semiconductor substrate and covering the gate structure; (c) performing a ultraviolet (UV) treatment on the first dielectric film; and (d) successively repeating the step (b) of deposition process and the step (c) of UV treatment at least once to form at least one second SiN film on the first SiN film until the total thickness of the first SiN film and the at least one second SiN film reaches the target thickness.

### BRIEF DESCRIPTION OF THE DRAWINGS

The aforementioned objects, features and advantages of this invention will become apparent by referring to the following detailed description of the preferred embodiments with reference to the accompanying drawings, wherein:

FIGS. 1 to 4 are cross-sectional diagrams illustrating an exemplary embodiment of a multi-layers curing-treated process for forming a tensile capping layer on an NMOS device.

### DETAILED DESCRIPTION OF ILLUSTRATIVE EMBODIMENTS

The present invention provides a method of forming tensile stress films for NFET performance enhancement, in which a multi-layers curing-treated process is performed to obtain the drive-current gain of NMOS device higher than the prior art through the use of single-layer UV-treated process. For forming a tensile capping layer on an NMOS device, a dielectric film is deposited to reach part of a target thickness followed by a curing process for film shrinkage. Then the process including the film deposition and the curing process is repeated for several times until the total thickness of the curing-treated dielectric films reaches the target thickness. In each repeated step, the deposition thickness and the curing treatment condition may be different, and the film deposition and the curing process may be performed in the same chamber or different chambers. The dielectric film may be SiN, SiON, SiO₂, or the like. The curing process may use ultraviolet light irradiation (called UV treatment), photo curing, thermal curing, e-beam curing, or any other advanced curing process.

Reference will now be made in detail to the present embodiments, examples of which are illustrated in the accompanying drawings. Wherever possible, the same reference numbers are used in the drawings and the description to refer to the same or like parts. In the drawings, the shape and thickness of one embodiment may be exaggerated for clarity and convenience. This description will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be present.

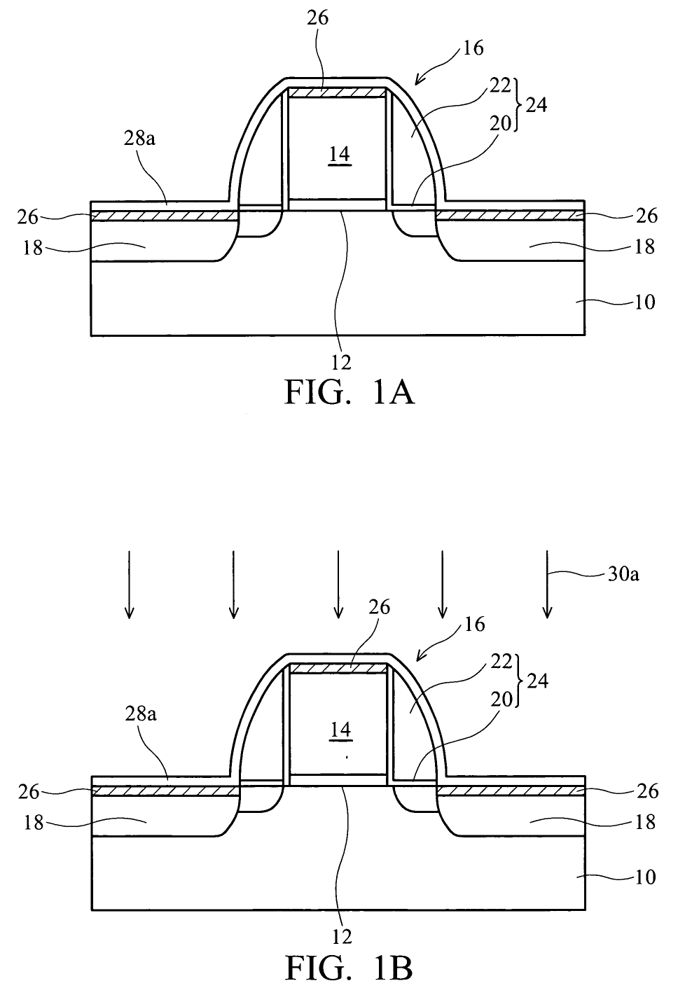

Herein, cross-sectional diagrams of FIGS. 1 to 4 illustrate an exemplary embodiment of a multi-layers curing-treated process for forming a tensile capping layer on an NMOS device. Referring to FIG. 1A, a semiconductor substrate 10 has a device region for forming an NMOS device. The semiconductor substrate 10 is bulk silicon, but other commonly used materials and structures such as silicon on insulator (SOI) or a silicon layer overlying a bulk silicon germanium may also be used. A gate structure 16 including a gate dielectric layer 12 and a gate electrode 14 is formed on the semiconductor substrate 10, and source/drain regions 18 are formed in the substrate 10 laterally adjacent to the gate structure 16. The gate dielectric 12 may be formed of silicon oxide or a high-k dielectric material. The gate electrode 14 may be formed of amorphous polysilicon, doped polysilicon, metal, single crystalline silicon or other conductive materials. For example of an NMOS transistor, the source/drain regions 18 are n-type and the substrate 10 is p-type. Through deposition and anisotropical etching processes, dielectric spacers 24 are formed on the sidewalls of the gate structure 16. The dielectric spacer 24 may be formed of oxide, nitride, oxynitride, or combinations thereof. For example, the dielectric spacer 24 includes an oxide liner 20 and a nitride layer 22. Although the embodiment of the present invention illustrates the dielectric spacer 24, the present invention also provides value when using a spacer free structure. A silicidation process is then performed to form silicide regions 26 on exposed semiconductor materials, such as the gate electrode 14 and the source/drain regions 18. The silicide region 26 may be a metal silicide layer comprising metals such as titanium, cobalt, nickel, palladium, platinum, erbium, and the like.

A first dielectric film 28a is then deposited on the resulted structure to reach part of the target thickness of the predetermined tensile capping layer. The first dielectric film 28a may be SiN, SiON or SiO₂, and SiN is preferred. The first dielectric film 28a may be formed by PVD, CVD or plasma assisted methods, such as using a plasma enhanced chemical vapor deposition (PECVD) system. The first dielectric film 28a has a thickness from about 2 nm to about 200 nm. Preferably, the first dielectric film 28a is about 5 nm to about 50 nm in thickness. For example, the PECVD SiN film deposition process is performed at the following conditions: high frequency power in the range of about 40˜200 watts (about 90-120 watts is preferred), low frequency power in the range of about 0˜250 watts (about 10˜200 watts is preferred), chamber pressure in the range of about 2˜10 Torr (about 3˜7 Torr is preferred), gas flow rate in the range of about 5K˜35K sccm (about 10K˜25K sccm is preferred), and chamber temperature in the range of about 300˜600° C. (about 350˜450° C. is preferred).

Referring to FIG. 1B, a first curing treatment 30a is performed on the first dielectric film 28a for film shrinkage. The first curing treatment 30a may be photo curing, thermal curing, e-beam curing, UV curing, or combinations thereof, and a UV treatment is preferred. For example, the UV treatment uses a UV light with a wave length of about 100˜600 nm (about 200˜400 nm is preferred) and performed at a UV power greater than about 300 W/m² (about 300˜1600 W/m² is preferred), a UV curing temperature about 300˜600° C. (about 350˜450° C. is preferred) for a curing time more than about 20 seconds. In another embodiment, the first curing treatment 30a is a thermal curing process using rapid thermal annealing (RTA) or furnace at about 400˜900° C. temperature. The first dielectric film 28a deposition and the first curing treatment 30a may be performed in the same chamber (in-situ) or different chambers (ex-situ). Experimentally, the UV-cured SiN film has a tensile stress greater than 0.5 GPa, and preferably greater than 1 GPa.

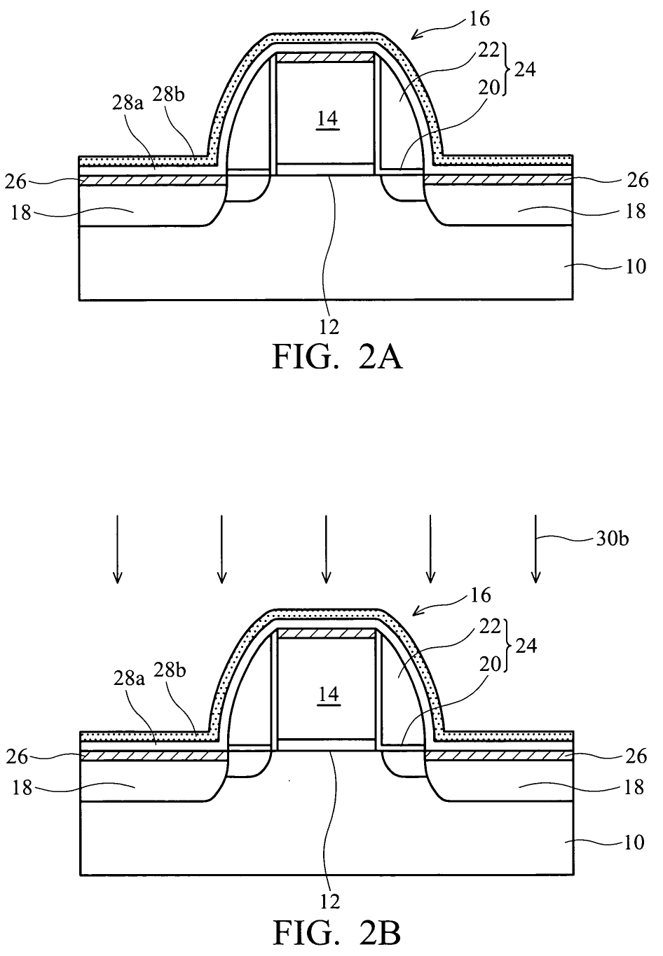

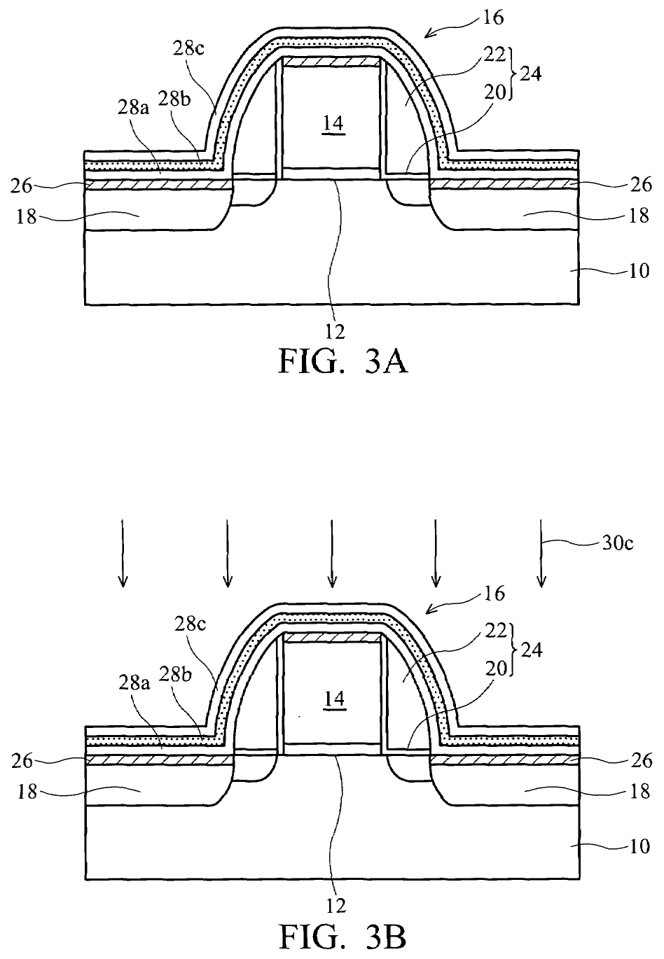

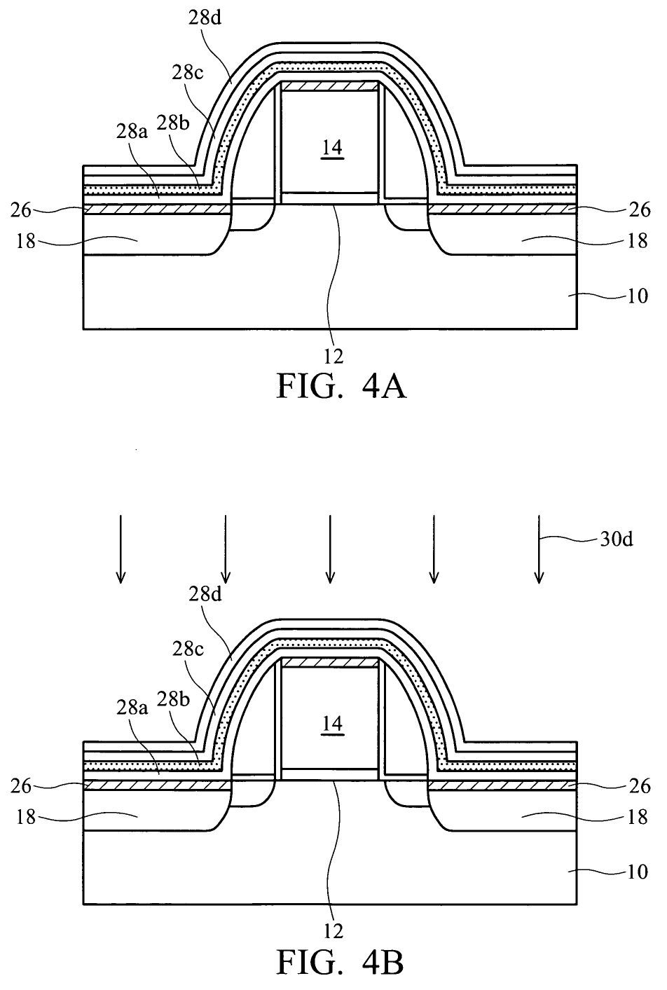

Next, for reaching the target thickness of 10˜200 nm (20˜150 nm is preferred) of the predetermined tensile capping layer on the NMOS device, the film deposition process and the curing treatment are repeated as illustrated in FIG. 2A-2B, FIG. 3A-3B, and FIG. 4A-4B,while explanation of the same or similar portions to the description in FIGS. 1A-1B is omitted herein. In FIG. 2A, a second dielectric film 28b is deposited on the resulted structure shown in FIG. 1B to reach part of the target thickness of the predetermined tensile capping layer. The second dielectric film 28b may be SiN, SiON or SiO₂, and SiN is preferred. The second dielectric film 28b may be formed by PVD, CVD or plasma enhanced chemical vapor deposition (PECVD). The second dielectric film 28b has a thickness from about 2 nm to about 200 nm. Preferably, the second dielectric film 28b is about 5 nm to about 50 nm in thickness. The thickness of the second dielectric film 28b may be the same as or different from the thickness of the first dielectric film 28a. In FIG. 2B, a second curing treatment 30b is performed on the second dielectric film 28b for film shrinkage. The second curing treatment 30b may be photo curing, thermal curing, e-beam curing, UV curing, or combinations thereof, and a UV treatment is preferred. The operating condition of second curing treatment 30b may be the same as or different from that of the first curing treatment 30a. The second dielectric film 28b deposition and the second curing treatment 30b may be performed in the same chamber (in-situ) or different chambers (ex-situ).

In FIG. 3A, a third dielectric film 28c is deposited on the resulted structure shown in FIG. 2B to reach part of the target thickness of the predetermined tensile capping layer. The third dielectric film 28c may be SiN, SiON, or SiO₂, and SiN is preferred. The third dielectric film 28c may be formed by PVD, CVD or plasma enhanced chemical vapor deposition (PECVD). The third dielectric film 28c has a thickness from about 2 nm to about 200 nm. Preferably, the third dielectric film 28c is about 5 nm to about 50 nm in thickness. The thickness of the third dielectric film 28c may be the same as or different from the thickness of the first dielectric film 28a and/or the second dielectric film 28b. In FIG. 3B, a third curing treatment 30c is performed on the third dielectric film 28c for film shrinkage. The third curing treatment 30c may be photo curing, thermal curing, e-beam curing, UV curing, or combinations thereof, and a UV treatment is preferred. The operating condition of the third curing treatment 30c may be the same as or different from that of the first curing treatment 30a and/or the second curing treatment 30b. The third dielectric film 28c deposition and the third curing treatment 30c may be performed in the same chamber (in-situ) or different chambers (ex-situ).

In FIG. 4A, a fourth dielectric film 28d is deposited on the resulted structure as shown in FIG. 3B. The fourth dielectric film 28d may be SiN, SiON, or SiO₂, and SiN is preferred. The fourth dielectric film 28d may be formed by PVD, CVD or plasma enhanced chemical vapor deposition (PECVD). The fourth dielectric film 28d has a thickness from about 2 nm to about 200 nm. Preferably, the fourth dielectric film 28d is about 5 nm to about 50 nm in thickness. The thickness of the fourth dielectric film 28d may be the same as or different from the thickness of the dielectric films 28a, 28b, 28c. In FIG. 4B, a fourth curing treatment 30d is performed on the fourth dielectric film 28d for film shrinkage. The fourth curing treatment 30d may be photo curing, thermal curing, e-beam curing, UV curing, or combinations thereof, and a UV treatment is preferred. The operating condition of the fourth curing treatment 30d may be the same or different from that of the curing treatment 30a, 30b, 30c. The fourth dielectric film 28d deposition and the fourth curing treatment 30d may be performed in the same chamber (in-situ) or different chambers (ex-situ).

The film deposition process and the curing treatment are repeated till the total thickness of the dielectric films 28a, 28b, 28c, 28d reaches the target thickness, thus acting not only a tensile stress capping film for introducing tensile strain into the NMOS device and enhancing its electron mobility, but also a contact etch stop layer (CESL) for controlling the end point during subsequent contact hole formation. Subsequently, post processes with temperature less than 600° C. will be implemented.

Although the present invention has been described in its preferred embodiments, it is not intended to limit the invention to the precise embodiments disclosed herein. Those skilled in this technology can still make various alterations and modifications without departing from the scope and spirit of this invention. Therefore, the scope of the present invention shall be defined and protected by the following claims and their equivalents.

What is claimed is:

1. A method of forming tensile stress films, comprising the steps of:
(a) providing a semiconductor substrate having a gate structure patterned thereon;
(b) performing a deposition process to form a first dielectric film overlying said semiconductor substrate and covering said gate structure;
(c) performing a curing process on said first dielectric film; and
(d) successively repeating the step (b) of deposition process and the step (c) of curing process at least once to form at least one second dielectric film on said first dielectric film until the total thickness of said first dielectric film and said at least one second dielectric film reaches a target thickness.

2. The method of claim 1, wherein the step (b) of deposition process uses a PECVD process to form a SiN film.

3. The method of claim 1, wherein the step (c) of curing process uses an ultraviolet (UV) light irradiation treatment.

4. The method of claim 3, wherein the step (c) of curing process uses a UV light with a wave length of about 100˜600 nm.

5. The method of claim 1, wherein the step (b) of deposition process forms a SiN film, a SiON film, a SiO₂ film, or combinations thereof.

6. The method of claim 1, wherein the step (c) of curing process uses photo curing, thermal curing, or e-beam curing.

7. The method of claim 1, wherein the step (b) of deposition process forms said first dielectric film between about 2 nm to 100 nm thick.

8. The method of claim 1, wherein said target thickness is between about 10 nm to 200 nm.

9. The method of claim 1, wherein the step (b) of deposition process and the step (c) of curing process are performed in different chambers.

10. A method of forming a tensile stress film having a target thickness, comprising the steps of:
(a) providing a semiconductor substrate having a gate structure patterned thereon;
(b) performing a deposition process to form a first SiN film overlying said semiconductor substrate and covering said gate structure;
(c) performing a ultraviolet (UV) treatment on said first dielectric film; and
(d) successively repeating the step (b) of deposition process and the step (c) of UV treatment at least once to form at least one second SiN film on said first SiN film until the total thickness of said first SiN film and said at least one second SiN film reaches said target thickness.

11. The method of claim 10, wherein the step (b) of deposition process uses a PECVD process.

12. The method of claim 10, wherein the step (c) of UV treatment uses a UV light with a wave length of about 100-600 nm.

13. The method of claim 10, wherein said first SiN film has a thickness between about 2 nm to 100 nm.

14. The method of claim 10, wherein said target thickness is between about 10 nm to 200 nm.

15. The method of claim 10, wherein the step (b) of deposition process and the step (c) of UV treatment are performed in different chambers.

16. The method of claim 10, wherein the step (b) of deposition process and the step (c) of UV treatment are performed in the same chamber.
